(19) United States
(12) Patent Application Publication
(10) Pub. No.: US 2025/0312888 A1
(43) Pub. Date: Oct. 9, 2025

(54) SUBSTRATE PROCESSING SYSTEM

(71) Applicant: KCTECH CO., LTD., Gyeonggi-do (KR)

(72) Inventors: Hee Sung CHAE, Gyeonggi-do (KR); Seung Eun LEE, Seoul (KR); Geun Sik YUN, Gyeonggi-do (KR)

(73) Assignee: KCTECH CO., LTD., Gyeonggi-do (KR)

(21) Appl. No.: 19/245,420

(22) Filed: Jun. 23, 2025

Related U.S. Application Data
(63) Continuation of application No. 17/495,816, filed on Oct. 7, 2021.

(30) Foreign Application Priority Data
Oct. 8, 2020 (KR) 10-2020-0130235
Oct. 8, 2020 (KR) 10-2020-0130254
Oct. 8, 2020 (KR) 10-2020-0130269
Aug. 30, 2021 (KR) 10-2021-0114782

(51) Int. Cl. B24B 37/34; B24B 27/00; B24B 37/10; B24B 41/00

(52) U.S. Cl. CPC B24B 37/345; B24B 27/0023; B24B 37/10; B24B 41/005

(57) ABSTRACT

A substrate processing system includes a front-end module, a first processing line including a first polishing line and a first cleaning line, a second processing line including a second polishing line and a second cleaning line and disposed in parallel to the first processing line, a first stage disposed between the first processing line and the second processing line, a first retransfer robot configured to transfer a substrate from the front-end module to the first stage, and a second retransfer robot having a single extensible arm configured to access the first polishing line, the first cleaning line, the second polishing line, the second cleaning line and the first stage and transfer the substrate between at least two locations of the first polishing line, the first cleaning line, the second polishing line, the second cleaning line and the first stage.

### CROSS-REFERENCE TO RELATED APPLICATION(S)

This is a continuation application of and claims the priority benefit of a prior application Ser. No. 17/495,816, filed on Oct. 7, 2021. The prior application Ser. No. 17/495,816 claims the benefit under 35 USC § 119 (a) of Korean Patent Application No. 10-2020-0130235 filed on Oct. 8, 2020, Korean Patent Application No. 10-2020-0130254 filed on Oct. 8, 2020, Korean Patent Application No. 10-2020-0130269 filed on Oct. 8, 2020, and Korean Patent Application No. 10-2021-0114782 filed on Aug. 30, 2021, in the Korean Intellectual Property Office, the entire disclosures of which are incorporated herein by reference for all purposes.

### BACKGROUND

### 1. Field

One or more example embodiments relate to a substrate processing system.

### 2. Description of Related Art

A chemical-mechanical polishing (CMP) process including polishing, buffing, and cleaning may be required to manufacture a semiconductor device. A semiconductor device may be provided in the form of a multilayer structure of which a substrate layer includes a transistor device having a diffusion region. In the substrate layer, a connecting metallic line may be patterned and electrically connected to the transistor device that constitutes a functional device. A patterned conductive layer may be insulated from other conductive layers through an insulator such as silicon dioxide. As more metal layers and corresponding insulating layers are formed, a need to smooth insulators may increase. When the insulators are not smoothed, numerous changes may occur on the surface, and manufacturing an additional metal layer may thus be more difficult. The metallic line pattern may be formed with an insulator, and a metal CMP process may be performed to remove excess metal.

To increase the production efficiency of the CMP process, a waiting time between processes or transfers may need to be reduced, and the processes or transfers may need to be performed in parallel. For example, the production efficiency of the CMP process may be improved by reducing a substrate transfer path and performing transfers and polishing simultaneously on a plurality of substrates.

The above description is information the inventor(s) acquired during the course of conceiving the present disclosure, or already possessed at the time, and is not necessarily art publicly known before the present application was filed.

### SUMMARY

Example embodiments provide a substrate s processing system that may simultaneously perform transfers and polishing on a plurality of substrates in parallel.

Example embodiments also provide a substrate processing system that may reduce a substrate transfer path and increase a transfer efficiency.

According to an aspect, there is provided a substrate processing system including a front-end module, a first processing line including a first polishing line and a first cleaning line, a second processing line including a second polishing line and a second cleaning line and disposed in parallel to the first processing line, a first stage disposed between the first processing line and the second processing line, and a first retransfer robot configured to transfer a substrate from the front-end module to the first stage.

The substrate processing system may further include a second retransfer robot configured to transfer the substrate between at least two locations of the first polishing line, the first cleaning line, the second polishing line, and the first stage.

Each of the first polishing line and the second polishing line may include a first rotating portion configured to form a first transfer orbit in a circle according to a rotation and transfer the substrate between a first transfer location and a second transfer location, a second rotating portion configured to form a second transfer orbit in a circle according to a rotation and transfer the substrate between the second transfer location and a polishing location, and a polishing pad configured to rotate at a location at which at least a portion of the polishing pad overlaps the polishing location.

The second retransfer robot may transfer a substrate in a state before polishing from the first stage to the first transfer location of one of the first polishing line and the second polishing line.

The first rotating portion may include at least one second stage to be disposed alternately at the first transfer location and the second transfer location.

The second rotating portion may include at least one carrier head to be disposed alternately at the second transfer location and the polishing location.

Each of the first polishing line and the second polishing line may further include a loading portion configured to load or unload the substrate from the second transfer location to the carrier head.

The loading portion may include a cleaning nozzle configured to clean the carrier head disposed at the second transfer location.

The second retransfer robot may transfer a substrate obtained after polishing from one of the first polishing line and the second polishing line to one of the first cleaning line and the second cleaning line.

The first retransfer robot may transfer a substrate obtained after cleaning from one of the first cleaning line and the second cleaning line to the front-end module.

Each of the first cleaning line and the second cleaning line may include a chamber portion including a plurality of cleaning chambers of which at least a portion is stacked in a vertical direction, and a third retransfer robot configured to transfer the substrate from at least one of the cleaning chambers to another one of the cleaning chambers.

The chamber portion may include a first chamber portion including at least one of the cleaning chambers, and a second chamber portion including at least one of the cleaning chambers and disposed separately from the first chamber portion in a horizontal direction. The third retransfer robot may be disposed between the first chamber portion and the second chamber portion.

The second retransfer robot may transfer a substrate obtained after polishing from one of the first polishing line and the second polishing line to the first chamber portion of one of the first cleaning line and the second cleaning line.

The first retransfer robot may transfer a substrate obtained after cleaning from the second chamber portion of one of the first cleaning line and the second cleaning line to the front-end module.

According to another aspect, there is provided a substrate processing system including a front-end module disposed in a first direction, a first processing line including a first polishing line and a first cleaning line and disposed in a second direction vertical to the first direction, a second processing line including a second polishing line and a second cleaning line and disposed in a third direction vertical to the first direction and parallel to the second direction, and a second retransfer robot disposed between the first processing line and the second processing line and configured to transfer a substrate between at least two locations of the first polishing line, the first cleaning line, the second polishing line, and the second cleaning line.

Each of the first polishing line and the second polishing line may include a first rotating portion configured to form a first transfer orbit in a circle according to a rotation and transfer the substrate between a first transfer location and a second transfer location, a second rotating portion configured to form a second transfer orbit in a circle according to a rotation and transfer the substrate between the second transfer location and a polishing location, and a polishing pad configured to rotate at a location at which at least a portion of the polishing pad overlaps the polishing location.

The first rotating portion may include at least one second stage to be disposed alternately at the first transfer location and the second transfer location.

The second rotating portion may include at least one carrier head to be disposed alternately at the second transfer location and the polishing location.

Each of the first polishing line and the second polishing line may further include a loading portion configured to load or unload the substrate from the second transfer location to the carrier head.

The loading portion may include a cleaning nozzle configured to clean the carrier head disposed at the second transfer location.

According to example embodiments described herein, a substrate processing system may perform polishing on a plurality of substrates, in succession and in parallel, thereby improving production efficiency.

According to example embodiments described herein, a substrate processing system may perform loading and/or unloading of a second substrate while polishing a first substrate, thereby improving production efficiency.

According to example embodiments described herein, a substrate processing system may reduce a substrate transfer path and increase transfer efficiency.

Additional aspects of the example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1 is a schematic plan view of a substrate processing system according to an example embodiment;

FIG. 2 is a schematic plan view of a first polishing line according to an example embodiment;

FIG. 3 is a schematic side view of a first rotating portion and a loading portion of a first polishing line according to an example embodiment;

FIG. 4 is a schematic perspective view of a first cleaning line according to an example embodiment;

FIG. 5 is a schematic side view of a first cleaning line in a substrate cleaning process according to an example embodiment; and

FIG. 6 is a schematic perspective view of a first chamber portion according to an example embodiment.

### DETAILED DESCRIPTION

Hereinafter, some example embodiments will be described in detail with reference to the accompanying drawings. However, various alterations and modifications may be made to the example embodiments. The example embodiments are not construed as limited to the disclosure and should be understood to include all changes, equivalents, and replacements within the idea and the technical scope of the disclosure.

The terminology used herein is for the purpose of describing particular examples only and is not to be limiting of the examples. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

It should be noted that if it is described in the specification that one component is “connected,” “coupled,” or “joined” to another component, a third component may be “connected,” “coupled,” and “joined” between the first and second components, although the first component may be directly connected, coupled or joined to the second component.

Unless otherwise defined, all terms used herein including technical or scientific terms have the same meanings as those generally understood consistent with and after an understanding of the present disclosure. Terms, such as those defined in commonly used dictionaries, should be construed to have meanings matching with contextual meanings in the relevant art and the present disclosure, and are not to be construed as an ideal or excessively formal meaning unless otherwise defined herein.

Hereinafter, the example embodiments will be described in detail with reference to the accompanying drawings. When describing the example embodiments with reference to the accompanying drawings, like reference numerals refer to like components and a repeated description related thereto will be omitted for increased clarity and conciseness.

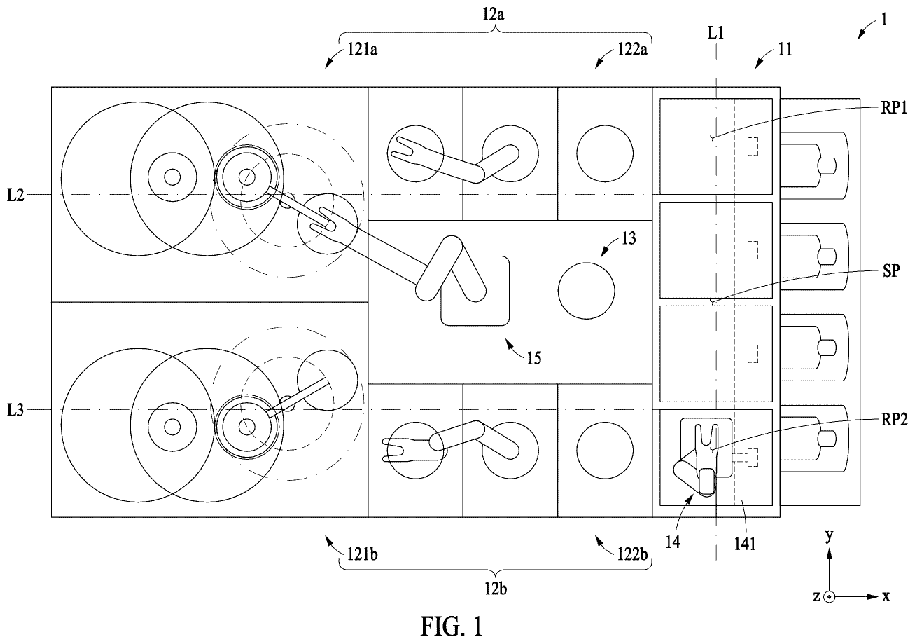

FIG. 1 is a schematic plan view of a substrate processing system according to an example embodiment.

Referring to FIG. 1, according to an example embodiment, a substrate processing system 1 may process the surface of a substrate. For example, the substrate processing system 1 may perform a polishing process and a cleaning process on the substrate. The substrate on which the processes are performed through the substrate processing system 1 may be, for example, a silicon wafer for manufacturing a semiconductor device. However, the type of the substrate is not limited to the foregoing example, and the substrate may include, for example, glass for a liquid crystal display (LCD), a plasma display panel (PDP), a flat panel display (FPD), or the like.

The substrate processing system 1 may include a front-end module 11, a processing line 12, a first stage 13, a first retransfer robot 14, and a second retransfer robot 15.

The front-end module 11 may be disposed on one side (e.g., a +x direction) of the substrate processing system 1. The front-end module 11 may be disposed in a first direction L1. For example, the front-end module 11 may be disposed to have a longitudinal direction of a y axis direction as illustrated in FIG. 1. The front-end module 11 may be an equipment front-end module (EFEM), for example. In the front-end module 11, a cassette or a front opening unified pod (FOUP) may be disposed. In the cassette or the FOUP, a substrate and/or wafer that has been processed or is to be processed may be stored. The first retransfer robot 14 may be disposed in the front-end module 11. The first retransfer robot 14 will be described hereinafter.

The processing line 12 may be a line on which processing of the substrate is performed. The processing line 12 may perform the polishing process and the cleaning process on the substrate. The processing line 12 may be provided as one or more processing lines. For example, as illustrated, the processing line 12 may include a first processing line 12a and a second processing line 12b. The first processing line 12a and the second processing line 12b may be disposed in parallel to each other. For example, the first processing line 12a may be disposed in a second direction L2 vertical to the first direction L1, and the second processing line 12b may be disposed in a third direction L3 vertical to the first direction L1 and parallel to the second direction L2. For example, the first processing line 12a may be disposed to have a longitudinal direction parallel to an x axis, and the second processing line 12b may also be disposed to have a longitudinal direction parallel to the x axis such that the second processing line 12b is parallel to the first processing line 12a. That is, the first processing line 12a and the second processing line 12b may be disposed to be parallel to each other. The first processing line 12a and the second processing line 12b may be disposed separately from each other such that a space is formed therebetween. For example, the first stage 13 and the second retransfer robot 15 to be described hereinafter may be disposed between the first processing line 12a and the second processing line 12b.

The first processing line 12a may include a first polishing line 121a and a first cleaning line 122a. The second processing line 12b may include a second polishing line 121b and a second cleaning line 122b.

The first polishing line 121a and the second polishing line 121b may perform the polishing process on the substrate. For example, the first polishing line 121a and the second polishing line 121b may perform chemical-mechanical polishing (CMP), or planarization, to polish or planarize the surface of the substrate. The first polishing line 121a and the second polishing line 121b may be disposed on an opposite side of the front-end module 11. For example, the first polishing line 121a and the second polishing line 121b may be disposed on another side (e.g., a-x direction) of the substrate processing system 1.

The first cleaning line 122a and the second cleaning line 122b may perform the cleaning process on the substrate. The cleaning process used herein may be construed as being a process including cleaning and drying. For example, the first cleaning line 122a and the second cleaning line 122b may clean a polished substrate obtained after polishing and dry a cleaned substrate obtained after cleaning. The first cleaning line 122a and the second cleaning line 122b may each be disposed to have a longitudinal direction parallel to the x axis.

For example, the first cleaning line 122a and the second cleaning line 122b may be disposed separately from each other such that a space is formed therebetween. The first cleaning line 122a and the second cleaning line 122b may be disposed between the first polishing line 121a and the front-end module 11 and between the second polishing line 121b and the front-end module 11, respectively.

The first stage 13 may be disposed between the first processing line 12a and the second processing line 12b. For example, the first stage 13 may be disposed between the first cleaning line 122a and the second cleaning line 122b. For example, the first stage 13 may be disposed between the front-end module 11, and the first polishing line 121a and the second polishing line 121b. The first stage 13 may be disposed adjacent to the front-end module 11. On the first stage 13, a substrate to be processed (e.g., an unpolished substrate in a state before polishing) may be seated.

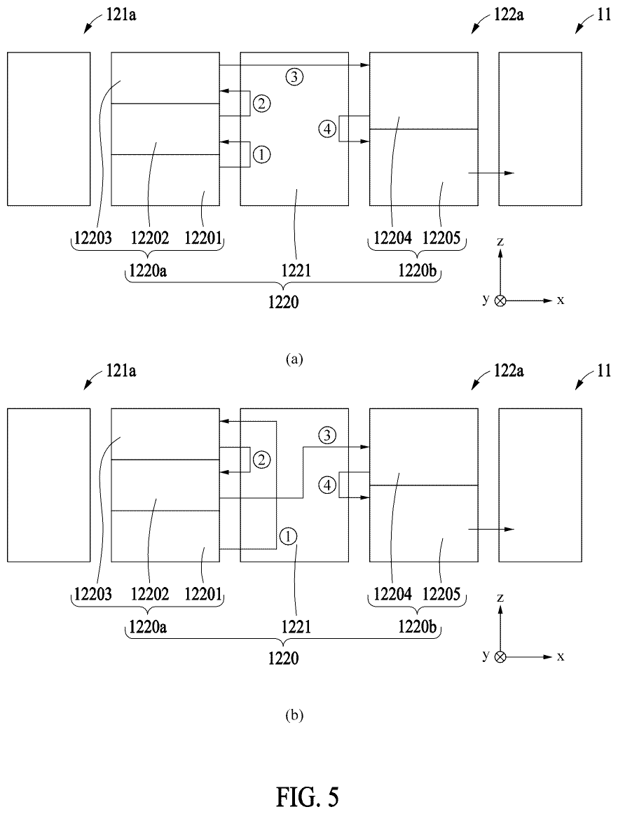

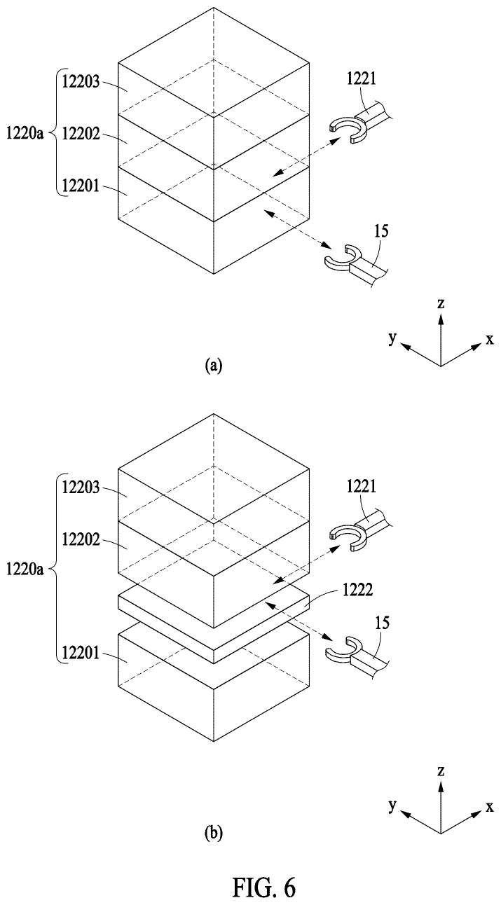

The first retransfer robot 14 may move along a longitudinal direction (e.g., a y axis direction) of the front-end module 11. For example, the first retransfer robot 14 may move along a rail 141 arranged in the y axis direction. For example, the first retransfer robot 14 may move between a first receiving point RPland a second receiving point RP2. A point used herein may indicate a location. The first receiving point RP1 may be a location adjacent to the first cleaning line 122a, and the second receiving point RP2 may be a location adjacent to the second cleaning line 122b. For example, the first receiving point RP1 may be disposed at one end (e.g., an end in a +y direction) of the rail 141, and the second receiving point RP2 may be disposed at another end (e.g., an end in a-y direction) of the rail 141. The first retransfer robot 14 may transfer a cleaned substrate obtained after cleaning from one of the first cleaning line 122a and the second cleaning line 122b to the front-end module 11. For example, the first retransfer robot 14 may transfer the cleaned substrate from a second chamber portion (e.g., a second chamber portion 1220b of FIG. 5) of one of the first cleaning line 122a and the second cleaning line 122b to the front-end module 11.

For example, at the first receiving point RP1, the first retransfer robot 14 may receive the cleaned substrate from the first cleaning line 122a. Also, at the second receiving point RP2, the first retransfer robot 14 may receive the cleaned substrate from the second cleaning line 122b. The first retransfer robot 14 may store the received cleaned substrate in the cassette or the FOUP.

Between the first receiving point RP1 and the second receiving point RP2, a supply point SP may be disposed. For example, the supply point SP may be disposed at a middle point between the first receiving point RP1 and the second receiving point RP2. At the supply point SP, the first retransfer robot 14 may transfer the substrate from the front-end module 11 to the first stage 13. For example, at the supply point SP, the first retransfer robot 14 may transfer a substrate to be processed from the cassette or the FOUP of the front-end module 11 to the first stage 13. The substrate to be processed may be seated on the first stage 13 and wait for a next transfer.

The second retransfer robot 15 may transfer the substrate between at least two locations of the first polishing line 121a, the first cleaning line 122a, the second polishing line 121b, the second cleaning line 122b, and the first stage 13. For example, the second retransfer robot 15 may transfer the substrate between at least two locations of the first polishing line 121a, the first cleaning line 122a, the second polishing line 121b, and the second cleaning line 122b. The second retransfer robot 15 may be disposed between the first processing line 12a and the second processing line 12b. For example, the second retransfer robot 14 may be disposed between the first cleaning line 122a and the second cleaning line 122b. For example, the second retransfer robot 15 may be disposed among the front-end module 11, the first polishing line 121a, and the second polishing line 121b. For example, the second retransfer robot 15 may be disposed more to the left (e.g., a-x direction) than the first stage 13 as illustrated in FIG. 1. The second retransfer robot 15 may be configured to rotate and include an extensible arm. The second retransfer robot 15 may be unrestrictedly accessible to any points in a circumference direction.

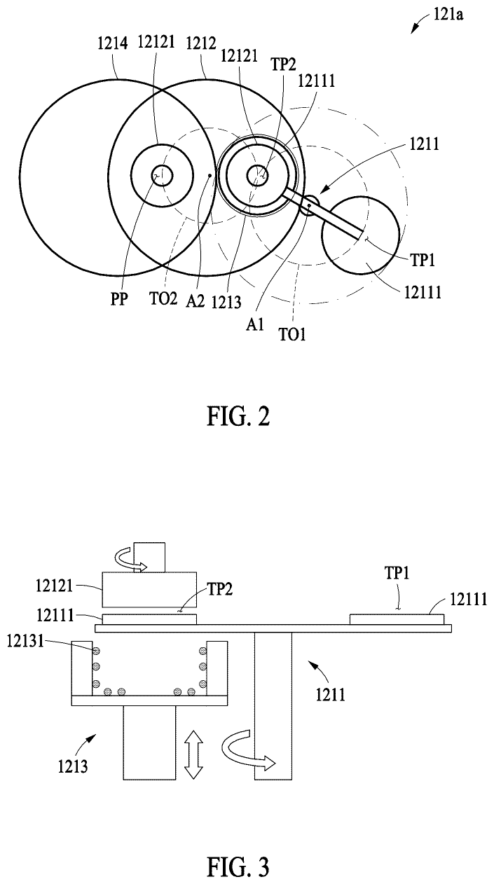

When the first retransfer robot 14 transfers a substrate to be processed (e.g., an unpolished substrate in a state before polishing) to the first stage 13, the second retransfer robot 15 may transfer the unpolished substrate that is seated on the first stage 13 to one of the first polishing line 121a and the second polishing line 121b. For example, the second retransfer robot 15 may transfer the unpolished substrate that is seated on the first stage 13 to a first transfer location (e.g., a first transfer point TP1 of FIG. 2) of the first polishing line 121a or a first transfer location (e.g., TP1) of the second polishing line 121b.

The second retransfer robot 15 may transfer a polished substrate obtained after polishing from one of the first polishing line 121a and the second polishing line 121b to one of the first cleaning line 122a and the second cleaning line 122b. For example, the second retransfer robot 15 may transfer the polished substrate from the first polishing line 121a to the first cleaning line 122a, and transfer the polished substrate from the second polishing line 121b to the second cleaning line 122b. However, examples are not limited to the foregoing example, and the second retransfer robot 15 may transfer the polished substrate from the first polishing line 121a to the second cleaning line 122b and transfer the polished substrate from the second polishing line 121b to the first cleaning line 122a. Using such a structure described above, even when one of the first cleaning line 122a and the second cleaning line 122b is broken or faulty, it is still possible to transfer a polished substrate to a cleaning line that is not broken or faulty, and it is thus possible to improve a process degree of freedom (DoF).

FIG. 2 is a schematic plan view of a first polishing line according to an example embodiment. FIG. 3 is a schematic side view of a first rotating portion and a loading portion of a first polishing line according to an example embodiment

Referring to FIGS. 2 and 3, according to an example embodiment, the first polishing line 121a may include a first rotating portion 1211, a second rotating portion 1212, a loading portion 1213, and a polishing pad 1214.

The first rotating portion 1211 may transfer a substrate along a first transfer orbit TO1 in a circle while rotating on a first axis A1 vertical to the ground. The first rotating portion 1211 may receive an unpolished substrate in a state before polishing through a second retransfer robot (e.g., the second retransfer robot 15 of FIG. 1). The first rotating portion 1211 may transfer the received substrate to the second rotating portion 1212. In addition, the first rotating portion 1211 may receive a polished substrate obtained after polishing from the second rotating portion 1212, and transfer the received substrate through the second retransfer robot 15 to a post-polishing process (e.g., a cleaning process). The first rotating portion 1211 may transfer a substrate along a circular orbit. The first rotating portion 1211 may simultaneously transfer a plurality of substrates. For example, a transfer of an unpolished substrate in a state before polishing and a transfer of a polished substrate obtained after polishing may be performed concurrently.

The first rotating portion 1211 may rotate on the first axis A1 vertical to the ground. The first rotating portion 1211 may rotate in one direction or both directions. The first rotating portion 1211 may include a second stage 12111.

The second stage 12111 may be connected to the first rotating portion 1211 to rotate integrally with the first rotating portion 1211. The second stage 12111 may support a lower surface of the substrate. The second stage 12111 may form the first transfer orbit TO1 according to a rotation of the first rotating portion 1211 and rotate on the first axis A1. The first transfer orbit TO1 may be formed in a circle. The second stage 12111 may transfer the substrate to one location (e.g., the first transfer point TP1 or the second transfer point TP2) on the first transfer orbit TO1 while rotating on the first axis A1 with the substrate being seated thereon.

The second stage 12111 may be provided as one or more second stages. For example, the second stage 12111 may be provided as a plurality of second stages. For example, as illustrated, the second stage 12111 may be provided as two second stages. The second stages may be disposed separately from each other at a preset interval therebetween based on the first axis A1. However, the number of second stages are not limited to the example number of second stages illustrated in FIGS. 1 and 2. A transfer of a substrate by the second stage 12111 will be described in detail hereinafter.

The second rotating portion 1212 may rotate on a second axis A2 vertical to the ground, and transfer the substrate along a second transfer orbit TO2 in a circle. The second rotating portion 1212 may rotate in one direction or in both directions. The second rotating portion 1212 may include a carrier head 12121.

The second rotating portion 1212 may support the carrier head 12121 from an upper side, and transfer the carrier head 12121 along the second transfer orbit TO2 with respect to the second axis A2. The substrate may be transferred by the second rotating portion 1212 while being gripped by the carrier head 12121. The carrier head 12121 may grip the substrate in an adsorbing and attachable manner through a membrane (not shown). A transfer of a substrate between the second stage 12111 and the carrier head 12121 may be performed by the loading portion 1213 to be described hereinafter.

The carrier head 12121 may frictionally contact the polishing pad 1214 and a polishing surface of the substrate to perform the polishing process. The carrier head 12121 and the polishing pad 1214 may polish the substrate through at least a relative rotational motion. For example, the carrier head 12121 may rotate and/or translate (or oscillate) to polish the substrate. In addition, to load/unload or polish the substrate, the carrier head 12121 may ascend and descend in a vertical direction.

The carrier head 12121 may be provided as a plurality of carrier heads. For example, as illustrated, the carrier head 12121 may be provided as two carrier heads. For example, when the carrier heads are connected to the second rotating portion 1212, the carrier heads may be disposed separately from each other at a preset interval therebetween with respect to the second axis A2. For example, the carrier heads may be disposed separately from each other at an equiangular interval from the second axis A2. However, the number of carrier heads is not limited to the foregoing example.

The loading portion 1213 may load an unpolished substrate in a state before polishing from the second stage 12111 to the carrier head 12121. The loading portion 1213 may unload a polished substrate obtained after polishing from the carrier head 12121 to the second stage 12111. The loading portion 1213 may load or unload the substrate by ascending and descending in a vertical direction. While the loading portion 1213 is loading or unloading the substrate, the first rotating portion 1211 (e.g., the second stage 12111) may ascend and descend in a vertical direction. The loading portion 1213 and the first rotating portion 1211 may be provided in an integral form. That is, the first rotating portion 1211 (e.g., the second stage 12111) may load or unload the substrate to the carrier head 12121 by itself through such a vertical direction ascending and descending operation, without an additional loading portion.

Hereinafter, the first transfer orbit TO1 of the first rotating portion 1211 will be described in detail with reference to FIGS. 2 and 3.

According to an example embodiment, a second retransfer robot (e.g., the second retransfer robot 15 of FIG. 2) may transfer an unpolished substrate in a state before polishing from a first stage (e.g., the first stage 13 of FIG. 1) to the second stage 12111 disposed at a first transfer point TP1. That is, the first rotating portion 1211 may receive the substrate from the second retransfer robot 15 at the first transfer point TP1 on the first transfer orbit TO1. The received substrate may be in a state being seated on the second stage 12111 disposed at the first transfer point TP1. In addition, the first rotating portion 1211 may transfer the substrate to the second retransfer robot 15 at the first transfer point TP1. For example, the first rotating portion 1211 may transfer a polished substrate obtained after polishing to a subsequent process (e.g., a cleaning process) through the second retransfer robot 15 from the first transfer point TP1. That is, a substrate waiting to be transferred may be disposed at the first transfer point TP1. At the first transfer point TP1, the second retransfer robot 15 may transfer the unpolished substrate from a cassette or a FOUP to the first rotating portion 1211, or transfer the polished substrate to a cleaning process, for example, the first cleaning line 122a or the second cleaning line 122b of FIG. 1.

The first transfer orbit TO1 and the second transfer orbit TO2 may overlap each other at the second transfer point TP2. At the second transfer point TP2, the substrate may be transferred from the first rotating portion 1211 to the second rotating portion 1212. For example, the first rotating portion 1211 may transfer (or load) an unpolished substrate in a state before polishing from the second transfer point TP2 to the second rotating portion 1212. In addition, at the second transfer point TP2, the substrate may be transferred from the second rotating portion 1212 to the first rotating portion 1211. For example, the second rotating portion 1212 may transfer (or unload) a polished substrate obtained after polishing from the second transfer point TP2 to the first rotating portion 1211. A transfer of the substrate between the first rotating portion 1211 and the second rotating portion 1212 performed at the second transfer point TP2 may be performed by the loading portion 1213. For this, the loading portion 1213 may be disposed at the second transfer point TP2. The loading portion 1213 may load the unpolished substrate from the second stage 12111 disposed at the second transfer point TP2 to the carrier head 12121 disposed at the second transfer point TP2. The loading portion 1213 may unload the substrate in a state after polishing from the carrier head 12121 disposed at the second transfer point TP2 to the second stage 12111 disposed at the second transfer point TP2.

According to an example embodiment, the second stage 12111 of the first rotating portion 1211 may be disposed alternately at the first transfer point TP1 and the second transfer point TP2 while rotating along the first transfer orbit TO1. For example, when one second stage 12111 is disposed at the first transfer point TP1, another second stage 12111 may be disposed at the second transfer point TP2. For example, when the second stage 12111 moves from the first transfer point TP1 to the second transfer point TP2 by a rotation of the first rotating portion 1211, the other second stage 12111 may move. That is, the first rotating portion 1211 may transfer a first substrate from the first transfer point TP1 to the second transfer point TP2, and simultaneously transfer a second substrate from the second transfer point TP2 to the first transfer point TP1.

Hereinafter, the second transfer orbit TO2 of the second rotating portion 1212 will be described in detail with reference to FIGS. 2 and 3.

According to an example embodiment, at the second transfer point TP2, the carrier head 12121 of the second rotating portion 1212 may receive (or load) an unpolished substrate in a state before polishing from the first rotating portion 1211. When the loading of the substrate is completed, the carrier head 12121 may move to a polishing location, for example, a polishing point PP, by a rotation of the second rotating portion 1212. The polishing point PP may be a location at which the second transfer orbit TO2 overlaps the polishing pad 1214. That is, at least a portion of the polishing pad 1214 may overlap the polishing point PP. At the polishing point PP, the substrate may be polished. That is, at the polishing point PP, the carrier head 12121 may polish an unpolished substrate in a state before polishing. When the polishing of the substrate is completed, the carrier head 12121 may move back to the second transfer point TP2 by a rotation of the second rotating portion 1212. At the second transfer point TP2, the carrier head 12121 may transfer (or unload) a polished substrate obtained after polishing to the first rotating portion 1211.

According to an example embodiment, while one substrate is being polished at the polishing point PP, another substrate may be transferred (or loaded) from the first rotating portion 1211 to the second rotating portion 1212 at the second transfer point TP2, or transferred (or unloaded) from the second rotating portion 1212 to the first rotating portion 1211 at the second transfer point TP2. That is, while one substrate is being polished in one carrier head 12121, another substrate may be loaded or unloaded in another carrier head 12121.

According to an example embodiment, the carrier head 12121 of the second rotating portion 1212 may be disposed alternately at the second transfer point TP2 and the polishing point PP while rotating along the second transfer orbit TO2. For example, when one carrier head 12121 is disposed at the second transfer point TP2, another carrier head 12121 may be disposed at the polishing point PP. When one carrier head 12121 moves from the second transfer point TP2 to the polishing point PP by a rotation of the second rotating portion 1212, another carrier head 12121 may move from the polishing point PP to the second transfer point TP2. That is, the second rotating portion 1212 may transfer one substrate from the polishing point PP to the second transfer point TP2, and simultaneously transfer another substrate from the second transfer point TP2 to the polishing point PP.

Hereinafter, the loading portion 1213 will be described in detail with reference to FIGS. 2 and 3.

According to an example embodiment, the loading portion 1213 may be disposed at the second transfer point TP2. At the second transfer point TP2, the loading portion 1213 may load a substrate from the second stage 12111 to the carrier head 12121, or unload the substrate from the carrier head 12121 to the second stage 12111. For this, the loading portion 1213 may be provided such that it is capable of ascending and descending in a vertical direction.

According to an example embodiment, the loading portion 1213 may further include a cleaning nozzle 12131. The cleaning nozzle 12131 may spray a cleaning solution to clean the carrier head 12121 disposed at the second transfer point TP2. For example, while the loading portion 1213 covers the carrier head 12121 at the second transfer point TP2, the cleaning nozzle 12131 may spray the cleaning solution to clean the carrier head 12121. In this example, the carrier head 12121 may be in a state where the substrate is not gripped by the carrier head 12121. By the cleaning solution sprayed from the cleaning nozzle 12131, a membrane (not shown) of the carrier head 12121 may be cleaned. Thus, it is possible to prevent polishing particles from being adhered to or fixed to the membrane. In addition, the carrier head 12121 may be cleaned by such an operation of the loading portion 1213 while the carrier head 12121 is being disposed at the second transfer point TP2, and it is thus possible to save space. Further, another carrier head 12121 may be cleaned at the second transfer point TP2 while one carrier head 12121 is polishing a substrate at the polishing point PP, and it is thus possible to save time.

According to an example embodiment, an additional injection nozzle (not shown) may be provided at the first transfer point TP1. The injection nozzle may spray pure water or the like while the substrate is seated on the second stage 12111 at the first transfer point TP1 to prevent the substrate from being dried in the air.

The second polishing line 121b is a component corresponding to the first polishing line 121a, and may be construed as being practically the same in its operations and functions as the first polishing line 121a described above with reference to FIGS. 2 and 3. Thus, for a detailed description of the second polishing line 121b, reference may be made to the description of the first polishing line 121a provided above.

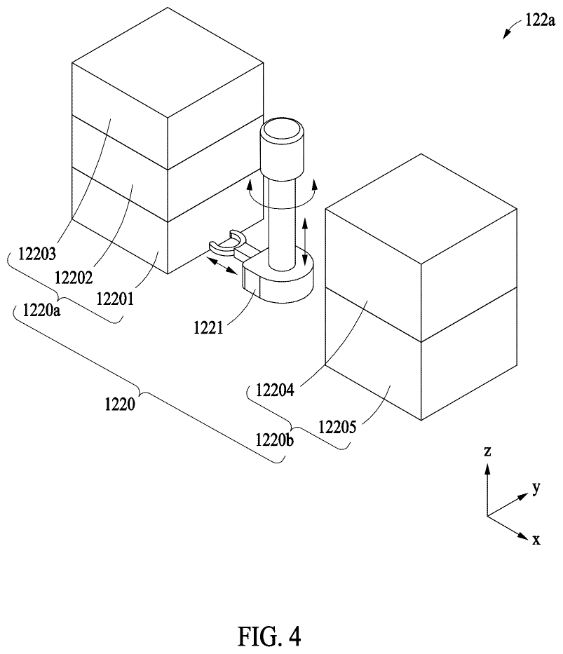

FIG. 4 is a schematic perspective view of a first cleaning line according to an example embodiment.

Referring to FIG. 4, according to an example embodiment, the first cleaning line 122a may perform a cleaning processing to clean a polished substrate. The first cleaning line 122a may include a chamber portion 1220 and a third retransfer robot 1221.

The chamber portion 1220 may provide a space in which the cleaning process is performed on the substrate. The chamber portion 1220 may be provided as a plurality of chamber portions. For example, as illustrated, the chamber portion 1220 may include a first chamber portion 1220a, and a second chamber portion 1220b disposed separately from the first chamber portion 1220a in a horizontal direction. However, the number of chamber portions is not limited to the foregoing example.

The chamber portion 1220 may include a cleaning chamber to clean the substrate. In the cleaning chamber, a nozzle configured to supply a cleaning solution for cleaning the substrate may be provided. The cleaning chamber may be provided as a plurality of cleaning chambers. For example, as illustrated, the chamber portion 1220 may include first through fifth cleaning chambers 12201, 12202, 12203, 12204, and 12205. In the first through fifth cleaning chambers 12201, 12202, 12203, 12204, and 12205, nozzles configured to supply different types of cleaning solution may be provided. At least a portion of the first through fifth cleaning chambers 12201, 12202, 12203, 12204, and 12205 may be a chamber in which cleaning of the substrate is performed, and another portion of the first through fifth cleaning chambers 12201, 12202, 12203, 12204, and 12205 may be a chamber in which drying of the cleaning solution is performed.

For example, as illustrated, the first chamber portion 1220a may include the first through third cleaning chambers 12201, 12202, and 12203, and the second chamber portion 1220b may include the fourth and fifth cleaning chambers 12204 and 12205. However, the number and arrangement of chambers are not limited to the foregoing example.

According to an example embodiment, a plurality of cleaning chambers may be stacked in a vertical direction. For example, as illustrated, the first through third cleaning chambers 12201, 12202, and 12203 of the first chamber portion 1220a may be stacked in sequential order from a lower side to an upper side (e.g., a +z axis direction) with respect to the ground. In addition, the fourth and fifth cleaning chambers 12204 and 12205 of the second chamber portion 1220b may be stacked in sequential order from the upper side to the lower side (e.g., a-z axis direction) with respect to the ground.

According to an example embodiment, the third retransfer robot 1221 may carry in, carry out, or transfer a substrate from or to a plurality of cleaning chambers. The third retransfer robot 1221 may support a lower surface of the substrate. For example, the third retransfer robot 1221 may include a grip portion configured to grip the substrate for a stable transfer. The third retransfer robot 1221 may be disposed between the first chamber portion 1220a and the second chamber portion 1220b. For example, the first chamber portion 1220a, the third retransfer robot 1221, and the second chamber portion 1220b may be disposed in a straight line in an x axis direction. However, the arrangement of the chamber portion 1220 and the third retransfer robot 1221 is not limited to the foregoing example. For example, when the chamber portion 1220 is provided as a plurality of chamber portions, the chamber portions may be disposed separately from each other along a circumference direction of the third retransfer robot 1221.

According to an example embodiment, the third retransfer robot 1221 may move in vertical and horizontal directions, and rotate on an axis vertical to the ground. Thus, the third retransfer robot 1221 may access unrestrictedly a plurality of cleaning chambers stacked in a vertical direction, and access unrestrictedly the first chamber 1220a and the second chamber 1220b disposed separately from each other in a horizontal direction.

FIG. 5 is a schematic side view of a first cleaning line in a substrate cleaning process according to an example embodiment.

Referring to FIG. 5, according to an example embodiment, the first cleaning line 122a may clean a substrate through a plurality of chambers 1220 using the third retransfer robot 1221.

According to an example embodiment, a cleaning chamber may include an entry and exit portion (not shown) in at least one direction through which a substrate enters and exits. For example, as illustrated, the third retransfer robot 1221 may carry a substrate into one of the first through fifth cleaning chambers 12201, 12202, 12203, 12204, and 12205. In addition, the third retransfer robot 1221 may wait for the substrate to be cleaned in the cleaning chamber. When the substrate is cleaned in the cleaning chamber, the third retransfer robot 1221 may carry out the substrate and transfer the substrate to another one of the first through fifth cleaning chambers 12201, 12202, 12203, 12204, and 12205. For example, as illustrated in (a) of FIG. 5, the third retransfer robot 1221 may transfer the substrate to the first through fifth cleaning chambers 12201, 12202, 12203, 12204, and 12205 in sequential order, starting from the first cleaning chamber 12201 to the second cleaning chamber 12202, the third cleaning chamber 12203, the fourth cleaning chamber 12204, and the fifth cleaning chamber 12205. For another example, as illustrated in (b) of FIG. 5, the third retransfer robot 1221 may transfer the substrate to the first through fifth cleaning chambers 12201, 12202, 12203, 12204, and 12205 in an order of the first cleaning chamber 12201, the third cleaning chamber 12203, the second cleaning chamber 12202, the fourth cleaning chamber 12204, and the fifth cleaning chamber 12205. Thus, it is possible to perform the cleaning process by changing a path through which the substrate is to be transferred without changing a location of a cleaning chamber or a cleaning solution when changing the order of cleaning solutions to be exposed to the substrate in the cleaning process, and it is thus possible to improve a process DoF. However, examples are not limited to the foregoing examples illustrated in (a) ad (b) of FIG. 5. For example, the third retransfer robot 1221 may be through a plurality of cleaning chambers in various orders. Also, a location of a cleaning chamber from which the cleaning process starts and a location of a cleaning chamber in which the cleaning process ends may be fixed. For example, the cleaning process may start in the first cleaning chamber 12201 and end in the fifth cleaning chamber 12205. In this example, the substrate for which cleaning is completed in the fifth cleaning chamber 12205 may be transferred to a cassette or a FOUP disposed in the front-end module 11 by a first retransfer robot (e.g., the first retransfer robot 14 of FIG. 1) disposed at a first receiving location (e.g., the first receiving point RP1 of FIG. 1).

FIG. 6 is a schematic perspective view of a first chamber portion according to an example embodiment.

Referring to FIG. 6, according to an example embodiment, the first chamber portion 1220a may receive a polished substrate through the second retransfer robot 15.

The second retransfer robot 15 may transfer the polished substrate from the first polishing line 121a or the second polishing line 121b to one of a plurality of cleaning chambers of the first cleaning line 122a or the second cleaning line 122b. For example, the second retransfer robot 15 may transfer the polished substrate that is seated on a second stage (e.g., the second stage 12111 of FIG. 2) disposed at a first transfer location (e.g., the first transfer point TP1 of FIG. 2) to one of the cleaning chambers of the first cleaning line 122a or the second cleaning line 122b. For example, the second retransfer robot 15 may transfer the polished substrate from one of the first polishing line 121a and the second polishing line 121b to the first chamber portion 1220a of one of the first cleaning line 122a and the second cleaning line 122b.

For example, as illustrated in (a) of FIG. 6, the second retransfer robot 15 may transfer a polished substrate from the first transfer point TP1 to the first cleaning chamber 12201 of the first chamber portion 1220a. However, the example illustrated in (a) of FIG. 6 is provided to help a better understanding of the description and does not limit a location at which the substrate is received from the second retransfer robot 15 to a certain location, for example, the first cleaning chamber 12201. For example, the second retransfer robot 15 may transfer the substrate to the second cleaning chamber 12202 or the third cleaning chamber 12203.

According to an example embodiment, the first cleaning line 122a may further include a transfer stage 1222. The second retransfer robot 15 may transfer a polished substrate from the first transfer point TP1 to the transfer stage 1222. The transfer stage 1222 may be disposed near a cleaning chamber. In addition, the transfer stage 1222 may be disposed between two neighboring cleaning chambers among a plurality of cleaning chambers. For example, as illustrated in (b) of FIG. 6, the transfer stage 1222 may be disposed between the first cleaning chamber 12201 and the second cleaning chamber 12202. However, the example illustrated in (b) of FIG. 6 is provided to help a better understanding of the description and does not limit a location at which the transfer stage 1222 is disposed to a certain location, for example, a location between the first cleaning chamber 12201 and the second cleaning chamber 12202. For example, the transfer stage 1222 may be disposed under the first cleaning chamber 12201, or disposed between the second cleaning chamber 12202 and the third cleaning chamber 12203. When the second retransfer robot 15 transfers the polished substrate to the transfer stage 1222, the third retransfer robot 1221 may transfer the substrate transferred to the transfer stage 1222 to one of the cleaning chambers.

The second cleaning line 122b may be a component corresponding to the first cleaning line 122a, and may be construed as being practically the same in its operations and functions as the first cleaning line 122a described above with reference to FIGS. 4 through 6. Thus, for a detailed description of the second cleaning line 122b, reference may be made to the description of the first cleaning line 122a provided above.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A substrate processing system, comprising:
a front-end module;
a first processing line comprising a first polishing line and a first cleaning line;
a second processing line comprising a second polishing line and a second cleaning line and disposed in parallel to the first processing line;
a first stage disposed between the first processing line and the second processing line;
a first retransfer robot configured to transfer a substrate from the front-end module to the first stage; and
a second retransfer robot having a single extensible arm configured to access the first polishing line, the first cleaning line, the second polishing line, the second cleaning line and the first stage and transfer the substrate between at least two locations of the first polishing line, the first cleaning line, the second polishing line, the second cleaning line and the first stage,
wherein the second retransfer robot is configured to transfer the substrate at least between the first polishing line and the first cleaning line, between the second polishing line and the second cleaning line, between the first polishing line and the second cleaning line, and between the second polishing line and the first cleaning line,
when one of the first cleaning line or the second cleaning line is broken or faulty, the second retransfer robot is configured to transfer a polished substrate to a cleaning line that is not broken or faulty,
wherein each of the first polishing line and the second polishing line comprises:
a first rotating portion configured to form a first transfer orbit in a circle according to a rotation and transfer the substrate between a first transfer location and a second transfer location;
a second rotating portion configured to form a second transfer orbit in a circle according to a rotation and transfer the substrate between the second transfer location and a polishing location; and
a polishing pad configured to rotate at a location at which at least a portion of the polishing pad overlaps the polishing location,
wherein an entirety of the second rotating portion rotates about an axis in a vertical direction, and the polishing pad overlaps the axis when viewed in the vertical direction,
wherein a central axis of the polishing pad is displaced from the axis when viewed in the vertical direction,
wherein the second retransfer robot is configured to transfer a substrate in a state before polishing from the first stage to the first transfer location of one of the first polishing line and the second polishing line,
wherein the first rotating portion comprises at least one second stage to be disposed alternately at the first transfer location and the second transfer location,
wherein the second rotating portion comprises at least one carrier head to be disposed alternately at the second transfer location and the polishing location.

2. The substrate processing system of claim 1, wherein each of the first polishing line and the second polishing line further comprises:
a loading portion configured to load or unload the substrate from the second transfer location to the carrier head.

3. The substrate processing system of claim 2, wherein the loading portion comprises:
a cleaning nozzle configured to clean the carrier head disposed at the second transfer location.

4. The substrate processing system of claim 1, wherein the second retransfer robot is configured to transfer a substrate obtained after polishing from one of the first polishing line and the second polishing line to one of the first cleaning line and the second cleaning line.

5. The substrate processing system of claim 4, wherein the first retransfer robot is configured to transfer a substrate obtained after cleaning from one of the first cleaning line and the second cleaning line to the front-end module.

6. The substrate processing system of claim 1, wherein each of the first cleaning line and the second cleaning line comprises:
a chamber portion comprising a plurality of cleaning chambers of which at least a portion is stacked in the vertical direction; and
a third retransfer robot configured to transfer the substrate from at least one of the cleaning chambers to another one of the cleaning chambers.

7. The substrate processing system of claim 6, wherein the chamber portion comprises:
a first chamber portion comprising at least one of the cleaning chambers; and
a second chamber portion comprising at least one of the cleaning chambers, and disposed separately from the first chamber portion in a horizontal direction,
wherein the third retransfer robot is disposed between the first chamber portion and the second chamber portion.

8. The substrate processing system of claim 7, wherein the second retransfer robot is configured to transfer a substrate obtained after polishing from one of the first polishing line and the second polishing line to the first chamber portion of one of the first cleaning line and the second cleaning line.

9. The substrate processing system of claim 8, wherein the first retransfer robot is configured to transfer a substrate obtained after cleaning from the second chamber portion of one of the first cleaning line and the second cleaning line to the front-end module.
